(19) United States
(12) Patent Application Publication
(10) Pub. No.: US 2025/0227390 A1
(43) Pub. Date: Jul. 10, 2025

(54) LINEAR SENSOR

(71) Applicant: SONY SEMICONDUCTOR SOLUTIONS CORPORATION, KANAGAWA (JP)

(72) Inventor: TAKANORI YAGAMI, KANAGAWA (JP)

(21) Appl. No.: 18/849,523

(22) PCT Filed: Feb. 10, 2023
(86) PCT No.: PCT/JP2023/004660

§ 371 Date: Sep. 22, 2024

(30) Foreign Application Priority Data
Mar. 30, 2022 (JP) 2022-057065

(51) Int. Cl. H04N 25/701; H01L 25/16; H04N 25/773; H10F 39/00

(52) U.S. Cl. CPC H04N 25/701; H01L 25/167; H04N 25/773; H10F 39/8037; H10F 39/811

(57) ABSTRACT

Provided is a linear sensor that can be further reduced in size. A linear sensor according to an aspect of the present disclosure includes a plurality of pixels each having a light receiving region that photoelectrically converts incident light and a non-light receiving region electrically connected to the light receiving region via a wire. The light receiving regions in the respective plurality of pixels are collectively arranged while being separated from the non-light receiving regions.

### TECHNICAL FIELD

The present disclosure relates to a linear sensor.

### BACKGROUND ART

A solid-state imaging element is, for example, a linear sensor that reads photocharges accumulated in a pn junction capacitor of a photodiode that is a photoelectric conversion element via a metal oxide semiconductor (MOS) transistor. In order to achieve size reduction and improve an aperture ratio of pixels, such a linear sensor has a laminated structure in which a first chip including a pixel substrate on which pixels are arranged and a second chip including a logic substrate on which a peripheral circuit is mounted are laminated.

### CITATION LIST

### Patent Document

Patent Document 1: WO 2016/136448 A

### SUMMARY OF THE INVENTION

### Problems to be Solved by the Invention

In the linear sensor having the laminated structure described above, an area of the first chip is determined depending on an area size of the second chip. Therefore, it is difficult to shrink the first chip to further reduce the size of the linear sensor because the area of the second chip needs to be secured to some extent. For example, it is difficult to reduce an area of a frame memory mounted on the second chip.

In view of this, the present disclosure provides a linear sensor that can be further reduced in size.

### Solutions to Problems

A linear sensor according to an aspect of the present disclosure includes a plurality of pixels each having a light receiving region that photoelectrically converts incident light and a non-light receiving region electrically connected to the light receiving region via a wire. The light receiving regions in the respective plurality of pixels are collectively arranged while being separated from the non-light receiving regions.

The light receiving regions may be arranged in a matrix.

The non-light receiving regions may be arranged in a matrix.

The linear sensor may further include:
a first chip on which at least the light receiving regions are arranged;
a second chip laminated on the first chip; and
a frame memory that is arranged on the second chip and stores image data generated on the basis of photoelectric conversion of the light receiving regions.

The non-light receiving regions may be arranged on the first chip.

The non-light receiving region may have a larger area than the light receiving region.

The non-light receiving regions may be arranged on the second chip, and
the wire may be a VLS wire extending in a lamination direction between the first chip and the second chip.

The light receiving region may have a larger area than the non-light receiving region.

The linear sensor may further include a third chip laminated between the first chip and the second chip, in which
the non-light receiving regions may be arranged on the third chip, and
the wire may be a VLS wire extending in a lamination direction between the first chip and the third chip.

The light receiving region may have an area equal to the non-light receiving region.

The linear sensor may further include:
a photoelectric conversion element that photoelectrically converts the incident light;
a floating diffusion layer that accumulates a charge generated by photoelectric conversion of the photoelectric conversion element;
a source follower transistor that amplifies a pixel signal generated on the basis of a charge amount accumulated in the floating diffusion layer; and
a pair of differential transistors that compares the pixel signal amplified by the source follower transistor with a reference signal.

The photoelectric conversion element and the floating diffusion layer may be arranged in the light receiving region, and
the source follower transistor and the pair of differential transistors may be arranged in the non-light receiving region.

The photoelectric conversion element, the floating diffusion layer, and the source follower transistor may be arranged in the light receiving region, and
the pair of differential transistors may be arranged in the non-light receiving region.

The one light receiving region may be shared by the plurality of non-light receiving regions.

The photoelectric conversion element may be a single photon avalanche diode (SPAD).

### BRIEF DESCRIPTION OF DRAWINGS

FIG. 1 is a block diagram showing a configuration example of an imaging device in a first embodiment.

FIG. 2 is an explanatory diagram showing a usage example of the imaging device in FIG. 1.

FIG. 3 shows an example of a laminated structure of a solid-state imaging element.

FIG. 4 is a block diagram showing a configuration example of a first chip.

FIG. 5 is a block diagram showing a configuration example of a second chip.

FIG. 6 is a circuit diagram showing a configuration example of a pixel.

FIG. 7 shows a layout of a pixel in the first embodiment.

FIG. 8 shows a layout of a pixel array section of a solid-state imaging element according to a comparative example.

FIG. 9 shows a layout of a pixel according to a comparative example.

FIG. 10 shows a layout of a pixel according to a second embodiment.

FIG. 11 shows a layout of a pixel according to a third embodiment.

FIG. 12 shows a layout of a pixel according to a fourth embodiment.

FIG. 13 shows a layout of a pixel according to a modification example of the fourth embodiment.

FIG. 14 is a block diagram showing a schematic configuration example of a vehicle control system.

FIG. 15 is an explanatory diagram showing an example of installation positions of imaging sections.

### MODE FOR CARRYING OUT THE INVENTION

Hereinafter, embodiments of an imaging device will be described with reference to the drawings. Although main components of the imaging device will be mainly described below, the imaging device may have components and functions that are not illustrated or described. The following description does not exclude components and functions that are not illustrated or described.

The drawings are schematic or conceptual, and a ratio of each portion and the like are not necessarily the same as actual ones. In the specification and the drawings, similar elements to those described above concerning the previously described drawings are denoted by the same reference signs, and detailed descriptions thereof are appropriately omitted.

### First Embodiment

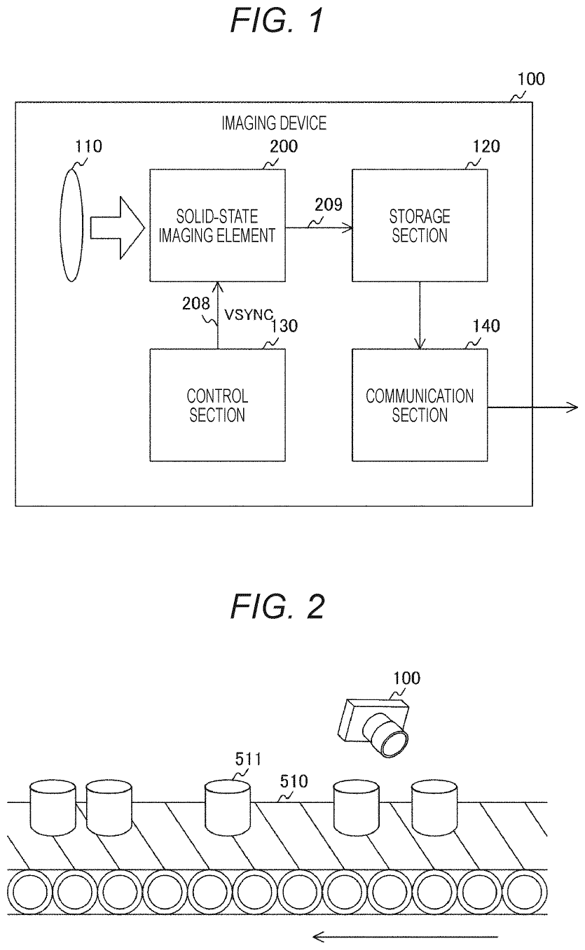

FIG. 1 is a block diagram showing a configuration example of an imaging device according to a first embodiment. An imaging device 100 in FIG. 1 includes an optical section 110, a solid-state imaging element 200, a storage section 120, a control section 130, and a communication section 140.

The optical section 110 collects incident light and guides the light to the solid-state imaging element 200. The solid-state imaging element 200 is an example of a linear sensor according to the present disclosure. Image data captured by the solid-state imaging element 200 is transmitted to the storage section 120 via a signal line 209.

The storage section 120 stores various types of data such as the above image data and a control program of the control section 130. The control section 130 controls the solid-state imaging element 200 to capture image data. For example, the control section 130 supplies a vertical synchronization signal VSYNC indicating an imaging timing to the solid-state imaging element 200 via a signal line 208. The communication section 140 reads the image data from the storage section 120 and transmits the image data to the outside.

FIG. 2 is an explanatory diagram showing a usage example of the imaging device 100. As shown in FIG. 2, the imaging device 100 is used in, for example, a factory in which a belt conveyor 510 is provided.

The belt conveyor 510 moves objects 511 in a predetermined direction at a constant speed. The imaging device 100 is fixed in the vicinity of the belt conveyor 510 and images the object 511 to generate image data. The image data is used for inspecting the presence or absence of a defect, for example. Therefore, factory automation (FA) is achieved.

Note that the imaging device 100 images the objects 511 moving at a constant speed, but is not limited to this configuration. The imaging device 100 may image an object while moving at a constant speed, for example, may perform aerial imaging.

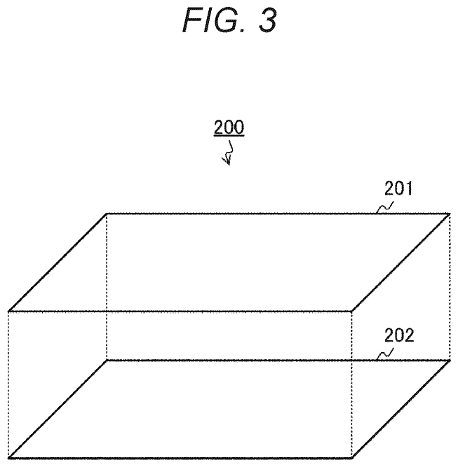

FIG. 3 shows an example of a laminated structure of the solid-state imaging element 200. The solid-state imaging element 200 includes a first chip 201 and a second chip 202 laminated on the first chip 201. Those chips are electrically connected via a connection portion such as a via. Note that the connection can also be made by a Cu—Cu bonding or a bump other than the via.

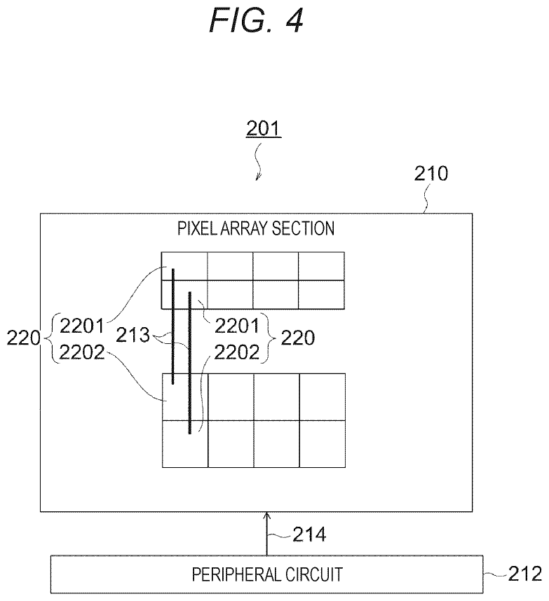

FIG. 4 is a block diagram showing a configuration example of the first chip 201. A pixel array section 210, a peripheral circuit 212, and the like are arranged on the first chip 201.

The pixel array section 210 includes a plurality of pixels 220. Each pixel 220 has a light receiving region 2201 that photoelectrically converts incident light and a non-light receiving region 2202 that reads a pixel signal generated by this photoelectric conversion.

The light receiving region 2201 of each pixel 220 is arranged separately from the non-light receiving region 2202 of each pixel 220. Further, the light receiving regions 2201 and the non-light receiving regions 2202 are collectively arranged in a matrix (two-dimensional array). Furthermore, in each pixel 220, the light receiving region 2201 and the non-light receiving region 2202 are electrically connected by a wire 213. Note that the regions are shown to be connected by one wire 213 in FIG. 4, but are actually connected by a plurality of wires 213.

In the peripheral circuit 212, for example, a circuit that supplies a DC voltage such as a power supply voltage VDD to the pixel array section 210 via a power supply line 214 is arranged.

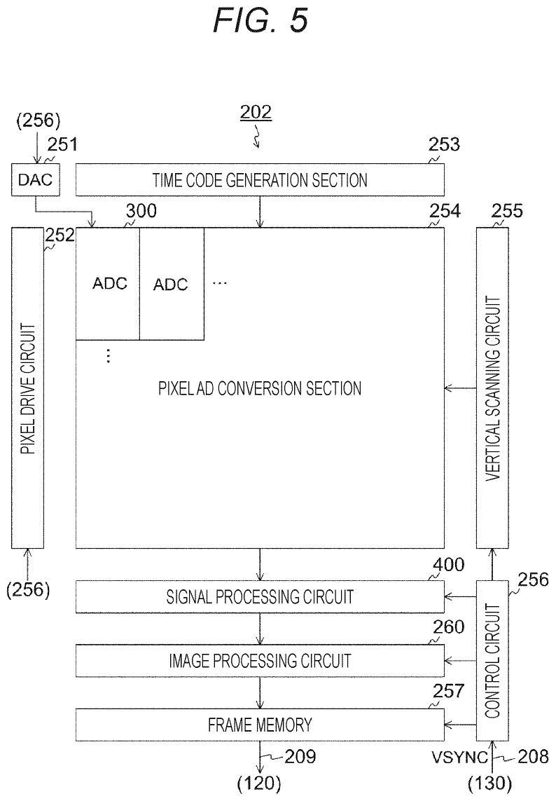

FIG. 5 is a block diagram showing a configuration example of the second chip 202. A digital to analog converter (DAC) 251, a pixel drive circuit 252, a time code generation section 253, a pixel AD conversion section 254, and a vertical scanning circuit 255 are arranged on the second chip 202. Further, a control circuit 256, a signal processing circuit 400, an image processing circuit 260, a frame memory 257, and the like are arranged on the second chip 202.

The DAC 251 generates a reference signal by digital-to-analog (DA) conversion in a predetermined AD conversion period. For example, a sawtooth ramp signal is used as the reference signal. The DAC 251 supplies the reference signal to the pixel AD conversion section 254.

The time code generation section 253 generates a time code indicating a time in the AD conversion period. The time code generation section 253 is achieved by, for example, a counter. The counter is, for example, a gray code counter. The time code generation section 253 supplies the time code to the pixel AD conversion section 254.

The pixel drive circuit 252 drives each of the pixels 220 to generate an analog pixel signal.

In the pixel AD conversion section 254, the same number of analog to digital converters (ADCs) 300 as the pixels 220 are arranged. Each ADC 310 performs AD conversion for converting the analog pixel signal generated by the corresponding pixel 220 into a digital signal. The pixel AD conversion section 254 generates image data in which the digital signals of the respective ADCs 310 are arrayed as a frame and transmits the frame to the signal processing circuit 400.

In the AD conversion, for example, the ADC 310 compares the pixel signal with the reference signal and holds a time code when a comparison result is inverted. Then, the ADC 310 outputs the held time code as a digital signal subjected to the AD conversion. Note that some of the ADCs 310 are arranged in the non-light receiving region 2202 of the first chip 201.

The vertical scanning circuit 255 drives the pixel AD conversion section 254 to execute AD conversion.

The signal processing circuit 400 performs predetermined signal processing on the frame. This signal processing includes, for example, correlated double sampling (CDS) processing and time delayed integration (TDI) processing. The signal processing circuit 400 supplies the processed frame to the image processing circuit 260.

The image processing circuit 260 performs predetermined image processing on the frame from the signal processing circuit 400. This image processing includes, for example, image recognition processing, black level correction processing, image correction processing, and demosaic processing. The image processing circuit 260 stores the processed frame in the frame memory 257.

The frame memory 257 temporarily stores the image data subjected to the image processing in units of frames. For example, the frame memory 257 can be a static random access memory (SRAM).

The control circuit 256 controls operation timings of the DAC 251, the pixel drive circuit 252, the vertical scanning circuit 255, the signal processing circuit 400, and the image processing circuit 260 in synchronization with the vertical synchronization signal VSYNC.

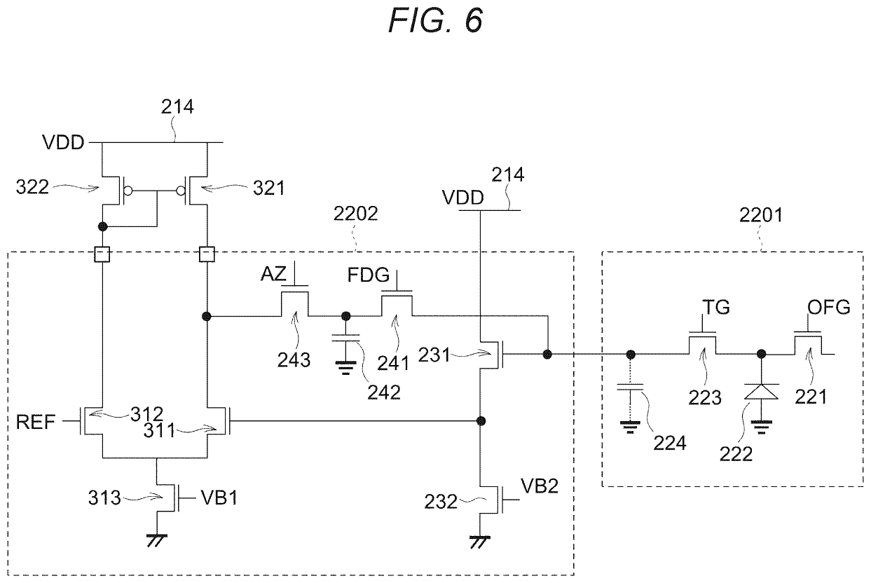

FIG. 6 is a circuit diagram showing a configuration example of the pixel 220. As described above, the pixel 220 has the light receiving region 2201 and the non-light receiving region 2202.

First, a circuit configuration of the light receiving region 2201 will be described. In the light receiving region 2201 of the present embodiment, a discharge transistor 221, a photoelectric conversion element 222, a transfer transistor 223, and a floating diffusion layer 224 are arranged. For example, the discharge transistor 221 and the transfer transistor 223 can be n-channel MOS transistors.

The discharge transistor 221 discharges a charge accumulated in the photoelectric conversion element 222 in response to a drive signal OFG from the above pixel drive circuit 252 (see FIG. 5).

The photoelectric conversion element 222 generates a charge by photoelectrically converting incident light. The photoelectric conversion element 222 can be a photodiode. The photodiode includes, for example, an avalanche photodiode such as a single photon avalanche diode (SPAD).

The transfer transistor 223 transfers a charge accumulated in the photoelectric conversion element 222 to the floating diffusion layer 224 in response to a transfer signal TG from the pixel drive circuit 252.

The floating diffusion layer 224 accumulates the charge transferred from the transfer transistor 223 and generates a pixel signal having a voltage corresponding to a charge amount.

Next, a circuit configuration of the non-light receiving region 2202 will be described. In the non-light receiving region 2202 of the present embodiment, a source follower transistor 231, a first current source transistor 232, a switching transistor 241, a capacitive element 242, an auto-zero transistor 243, a first differential transistor 311, a second differential transistor 312, and a second current source transistor 313 are arranged. Each transistor of the non-light receiving region 2202 can be, for example, an n-channel MOS transistor.

A semiconductor well region for forming each transistor of the non-light receiving region 2202 is separated from a semiconductor well region for forming each MOS transistor of the light receiving region 2201 by an element isolation film such as shallow trench isolation (STI). Meanwhile, the MOS transistors are electrically connected by the wire 213 (see FIG. 4).

A gate of the source follower transistor 231 is connected to one end of the floating diffusion layer 224. Further, a source of the source follower transistor 231 is connected to a drain of the first current source transistor 232.

The first current source transistor 232 functions as a source follower circuit that amplifies a pixel signal together with the source follower transistor 231. A predetermined bias voltage VB2 is applied to a gate of the first current source transistor 232. A predetermined ground voltage is applied to a source thereof. As a result, the first current source transistor 232 supplies a current corresponding to the bias voltage VB2 to the source follower transistor 231.

A drain of the switching transistor 241 is connected to the floating diffusion layer 224 and the gate of the source follower transistor 231. A source of the switching transistor 241 is connected to one end of the capacitive element 242 and a drain of the auto-zero transistor 243. The other end of the capacitive element 242 is grounded. A switching signal FDG is input from the pixel drive circuit 252 to a gate of the switching transistor 241. The switching transistor 241 is turned on or off in response to the switching signal FDG. Therefore, an electrical connection between the floating diffusion layer 224 and the capacitive element 242 is switched.

The auto-zero transistor 243 short-circuits a drain of the first differential transistor 311 and an input node of the source follower circuit in response to an auto-zero signal AZ from the pixel drive circuit 252.

The first differential transistor 311 and the second differential transistor 312 form a pair. That is, sources of those transistors are both connected to a drain of the second current source transistor 313. The drain of the first differential transistor 311 is connected to a drain of a first current transistor 321. A pixel signal amplified by the source follower transistor 231 is input to a gate of the first differential transistor 311. Meanwhile, a drain of the second differential transistor 312 is connected to a drain and gate of a second current transistor 322. A reference signal REF from the DAC 251 is input to a gate of the second differential transistor 312.

Both the first current transistor 321 and the second current transistor 322 are configured by p-channel MOS transistors and function as a current mirror circuit. A power supply voltage VDD is applied to each source of the first and second current transistors 321 and 322.

A predetermined bias voltage VB1 is applied to a gate of the second current source transistor 313, and a predetermined ground voltage is applied to a source of the second current source transistor 313. The second current source transistor 313 supplies a current corresponding to the bias voltage VB1.

The first differential transistor 311, the second differential transistor 312, the second current source transistor 313, the first current transistor 321, and the second current transistor 322 described above function as a differential amplifier circuit that amplifies a difference between the pixel signal input to the gate of the first differential transistor 311 and the reference signal REF input to the gate of the second differential transistor 312. The differential amplifier circuit is a part of the ADC 300 described above.

Note that the circuit configuration of the pixel 220 is not limited to a pixel ADC in which the ADC 300 is provided for each pixel 220 as shown in FIG. 6. The pixel 220 may have, for example, a circuit configuration including a SPAD as the photoelectric conversion element 222 or a circuit configuration in which a charge at the time of reset and a charge at the time of exposure are accumulated in different capacitive elements.

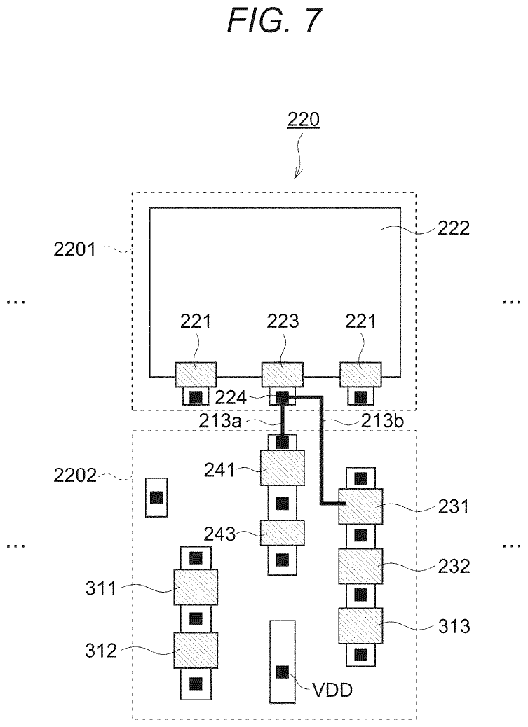

FIG. 7 shows a layout of the pixel 220 in the first embodiment. In the layout of FIG. 7, the floating diffusion layer 224 arranged in the light receiving region 2201 faces the switching transistor 241 arranged in the non-light receiving region 2202. Further, the source follower transistor 231 is arranged near the switching transistor 241. Therefore, the floating diffusion layer 224 is connected to the switching transistor 241 by a wire 213a and is also connected to the source follower transistor 231 by a wire 213b different from the wire 213a.

Note that, in the present embodiment, the non-light receiving region 2202 has a larger area than the light receiving region 2201. However, an area ratio of both the regions is not particularly limited. Further, in the present embodiment, the non-light receiving region 2202 is separately arranged on the lower side of the light receiving region 2201 in a column direction, but may be separately arranged on the upper side thereof in the column direction or may be separately arranged in a row direction orthogonal to the column direction.

Here, the solid-state imaging element 200 according to the present embodiment configured as described above will be described in comparison with a solid-state imaging element according to a comparative example. Note that, in the solid-state imaging element according to the comparative example, components similar to those of the solid-state imaging element 200 according to the present embodiment are denoted by the same reference signs, and detailed descriptions thereof will be omitted.

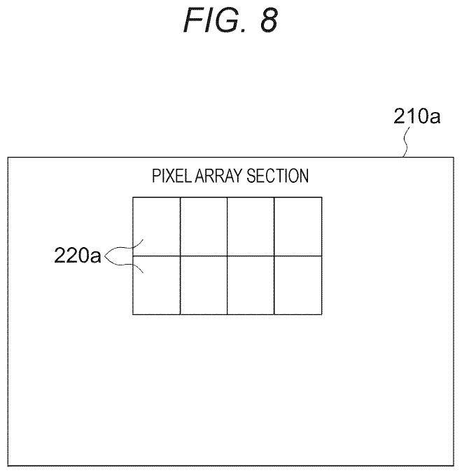

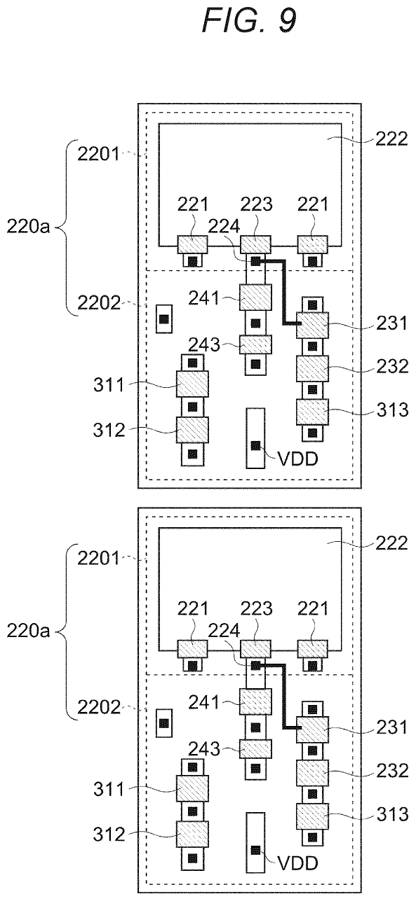

FIG. 8 shows a layout of a pixel array section of the solid-state imaging element according to the comparative example. Further, FIG. 9 shows a layout of a pixel according to the comparative example.

In a pixel array section 210a according to the present comparative example, pixels 220a are arranged in a two-dimensional array as shown in FIG. 8. Further, as shown in FIG. 9, each pixel 220a has the light receiving region 2201 and the non-light receiving region 2202. However, in the present comparative example, the light receiving region 2201 and the non-light receiving region 2202 are not separated and are arranged adjacent to each other in the column direction (longitudinal direction). Therefore, in the pixel array section 210a, the light receiving regions 2201 and the non-light receiving regions 2202 are alternately arranged in the column direction.

Because the present comparative example has the arrangement configuration described above, imaged parts and non-imaged parts are alternately generated due to the non-light receiving regions 2202 at each imaging timing when the object 511 is imaged along the column direction. Therefore, the number of times of imaging required for imaging the object 511 increases, and as a result, a large-capacity frame memory 257 is required. When the capacity of the frame memory 257 is large, it is difficult to reduce the area of the second chip 202.

Meanwhile, in the pixel array section 210 according to the present embodiment, the light receiving region 2201 and the non-light receiving region 2202 of each pixel 220 are arranged separately from each other in the column direction as described above. Further, in the pixels 220, the light receiving regions 2201 are collectively arranged in a matrix. Therefore, when the object 511 is imaged along the column direction, the non-imaged parts caused by the non-light receiving regions 2202 are not generated at each imaging timing. Therefore, in the present embodiment, the capacity of the frame memory 257 can be reduced by half as compared with the comparative example.

Therefore, according to the present embodiment, the area of the second chip 202 can be reduced, and thus the area of the first chip 201 can also be reduced. As a result, the area of the entire chip can be reduced, and thus further reduction in size can be achieved.

### Second Embodiment

Hereinafter, a second embodiment of the present disclosure will be described. Here, differences from the first embodiment will be mainly described, and description of similar points will be appropriately omitted.

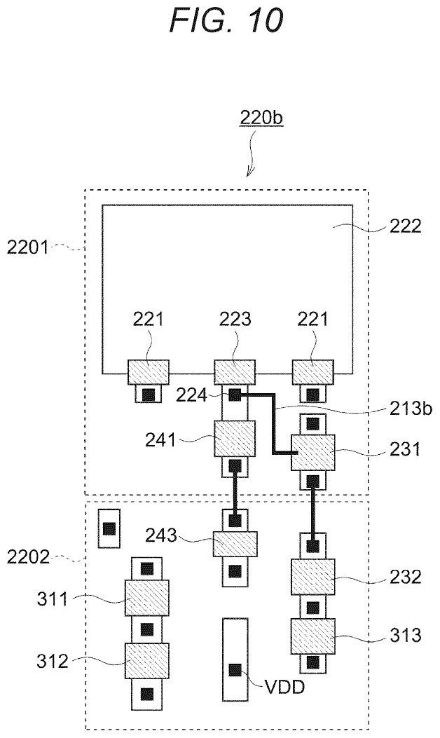

FIG. 10 shows a layout of a pixel according to the second embodiment. A pixel 220b according to the present embodiment has the same circuit configuration as the pixel 220 according to the first embodiment described above. Meanwhile, circuit elements arranged in the light receiving region 2201 and the non-light receiving region 2202 are different from those of the pixel 220 according to the first embodiment. Specifically, in the present embodiment, the source follower transistor 231 and the switching transistor 241 are arranged not in the non-light receiving region 2202, but in the light receiving region 2201. Further, the floating diffusion layer 224 is connected to the source follower transistor 231 via the wire 213b.

In the pixel 220b according to the present embodiment configured as described above, as well as in the first embodiment, the light receiving region 2201 and the non-light receiving region 2202 are separately arranged on the first chip 201. Further, the light receiving regions 2201 of the plurality of pixels 220b are collectively arranged on the first chip 201. Therefore, the capacity of the frame memory 257 can be reduced. Therefore, the area of the second chip 202 can be reduced, and thus the area of the first chip 201 can also be reduced. As a result, the area of the entire chip can be reduced, and thus reduction in size can be achieved.

Furthermore, in the present embodiment, the source follower transistor 231 is arranged in the same light receiving region 2201 as the floating diffusion layer 224 as described above. Therefore, the length of the wire 213b connecting the two components is shorter than that in the first embodiment. As a result, conversion efficiency can be improved.

### Third Embodiment

Hereinafter, a third embodiment of the present disclosure will be described. Also here, differences from the first embodiment will be mainly described, and description of similar points will be appropriately omitted.

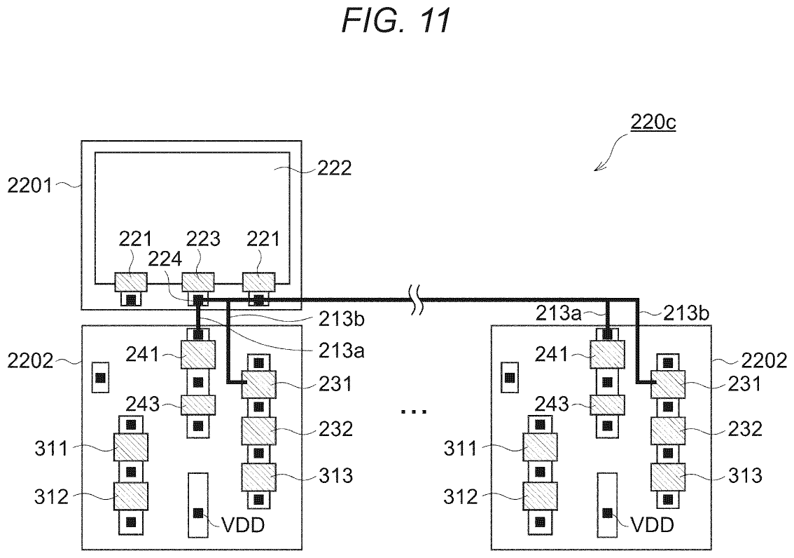

FIG. 11 shows a layout of a pixel according to the third embodiment. In a pixel 220c according to the present embodiment, circuit elements arranged in the light receiving region 2201 and the non-light receiving region 2202 are the same as those in the first embodiment. Meanwhile, the pixel 220c is different from the pixel 220 according to the first embodiment in having a plurality of non-light receiving regions 2202.

Specifically, the source follower transistors 231 arranged in the respective plurality of non-light receiving regions 2202 are all connected to one floating diffusion layer 224 arranged in the light receiving region 2201 via the wires 213b. Further, the switching transistors 241 arranged in the respective plurality of non-light receiving regions 2202 are all connected to the floating diffusion layer 224 via the wires 213a. That is, in the pixel 220c according to the present embodiment, one light receiving region 2201 is shared by the plurality of non-light receiving regions 2202.

In the present embodiment configured as described above, one pixel 220c has the plurality of non-light receiving regions 2202. Thus, the non-light receiving region 2202 has a larger circuit area than those in the first and second embodiments described above. However, in the pixel 220c, the light receiving region 2201 is arranged separately from the non-light receiving regions 2202 on the first chip 201 as in those embodiments. Further, the light receiving regions 2201 of the plurality of pixels 220c are collectively arranged in the first chip 201. Therefore, the capacity of the frame memory 257 can be reduced as in other embodiments. Therefore, the area of the second chip 202 can be reduced as compared with the above comparative example. As a result, the area of the entire chip can be reduced, and thus reduction in size can be achieved.

Furthermore, in the present embodiment, one light receiving region 2201 is shared by the plurality of non-light receiving regions 2202 as described above. Therefore, it is possible to read a pixel signal generated by photoelectric conversion in the light receiving region 2201 at a high speed. It is possible to speed up processing from reception of incident light to creation of image data.

### Fourth Embodiment

Hereinafter, a fourth embodiment of the present disclosure will be described. Also here, differences from the first embodiment will be mainly described, and description of similar points will be appropriately omitted.

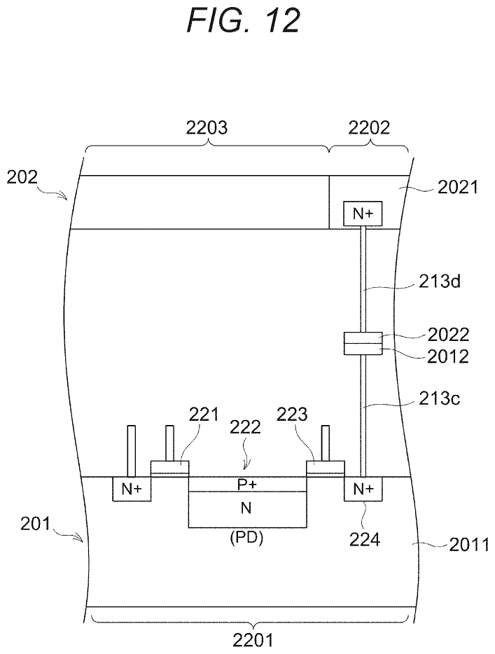

FIG. 12 shows a layout of a pixel according to the fourth embodiment. In the present embodiment, circuit elements arranged in the light receiving region 2201 and the non-light receiving region 2202 are the same as those in the first embodiment. Meanwhile, in the present embodiment, the light receiving region 2201 is arranged on a substrate 2011 of the first chip 201, whereas the non-light receiving region 2202 is arranged on a substrate 2021 of the second chip 202. Further, the light receiving region 2201 has a larger area than the non-light receiving region 2202.

Note that the substrate 2021 also has a logic region 2203 adjacent to the non-light receiving region 2202. In the logic region 2203, the peripheral circuit including the frame memory 257 and the like shown in FIG. 5 are arranged.

Further, in the present embodiment, a pad 2012 is provided above the first chip 201, and a pad 2022 is provided below the second chip 202. The pad 2012 and the pad 2022 are, for example, copper pads and are bonded to each other. Further, the first chip 201 is provided with a VLS wire 213c extending in a lamination direction (vertical direction) between the pad 2012 and the floating diffusion layer 224. Meanwhile, the second chip 202 is provided with a VLS wire 213d extending in the lamination direction between the pad 2022 and the non-light receiving region 2202 of the substrate 2021. As described above, the floating diffusion layer 224 is connected to the source follower transistor 231 and the switching transistor 241 arranged in the non-light receiving region 2202 via the VLS wires 213c and 213d and the pads 2012 and 2022.

In the pixel according to the present embodiment configured as described above, light is incident on the photoelectric conversion element 222 from the lower side of FIG. 12 toward the substrate 2011. Therefore, a pixel signal is generated. This pixel signal is read from the light receiving region 2201 to the non-light receiving region 2202 provided in the second chip 202. The read pixel signal is processed by various circuits provided in the logic region 2203 and is stored in the frame memory 257 as image data. At this time, also in the present embodiment, the light receiving regions 2201 of the respective pixels are collectively arranged in the first chip 201 while being separated from the non-light receiving regions 2202. Therefore, the area of the frame memory 257 can be reduced as in the other embodiments described above.

Furthermore, in the present embodiment, the non-light receiving region 2202 is arranged on the second chip 202 different from the first chip 201. Therefore, a light receiving area of the photoelectric conversion element 222 can be enlarged in the first chip 201.

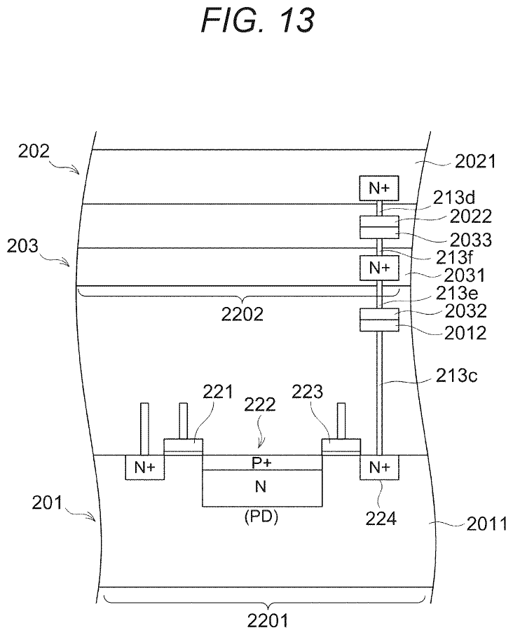

FIG. 13 shows a layout of a pixel according to a modification example of the fourth embodiment. Here, differences from the above fourth embodiment will be mainly described.

In the present modification example, a third chip 203 is laminated between the first chip 201 and the second chip 202. The non-light receiving region 2202 of the pixel is arranged on a substrate 2031 of the third chip 203. The non-light receiving region 2202 has an area substantially equal to the light receiving region 2201. A pad 2032 bonded to the pad 2012 is provided below the third chip 203. Further, the third chip 203 is also provided with a VLS wire 213e extending in the lamination direction from the pad 2032 to the substrate 2031. The floating diffusion layer 224 arranged in the light receiving region 2201 of the first chip 201 is connected to the source follower transistor 231 and the switching transistor 241 arranged in the non-light receiving region 2202 via the VLS wire 213c, the pad 2012, the pad 2032, and the VLS wire 213e.

Further, a pad 2033 bonded to the pad 2022 is provided above the third chip 203. Further, the third chip 203 is also provided with a VLS wire 213f extending in the lamination direction from the pad 2033 to the substrate 2031. The circuit element arranged in the non-light receiving region 2202 of the third chip 203 is connected to the peripheral circuit including the frame memory 257 and the like formed on the second chip via the VLS wire 213f, the pad 2033, the pad 2022, and the VLS wire 213d.

In the pixel according to the present modification example configured as described above, the light receiving regions 2201 of the respective pixels are collectively arranged in the first chip 201 while being separated from the non-light receiving regions 2202. Therefore, the area of the frame memory 257 can be reduced as in the fourth embodiment described above.

Furthermore, in the present modification example, the non-light receiving region 2202 is arranged on the third chip 203 different from the first chip 201 or the second chip 202. Therefore, it is possible to enlarge the light receiving area of the photoelectric conversion element 222 in the first chip 201 while reducing the area of the second chip 202.

### <Application Example to Mobile Body>

The technology according to the present disclosure (the present technology) is applicable to various products. For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a ship, a robot, and the like.

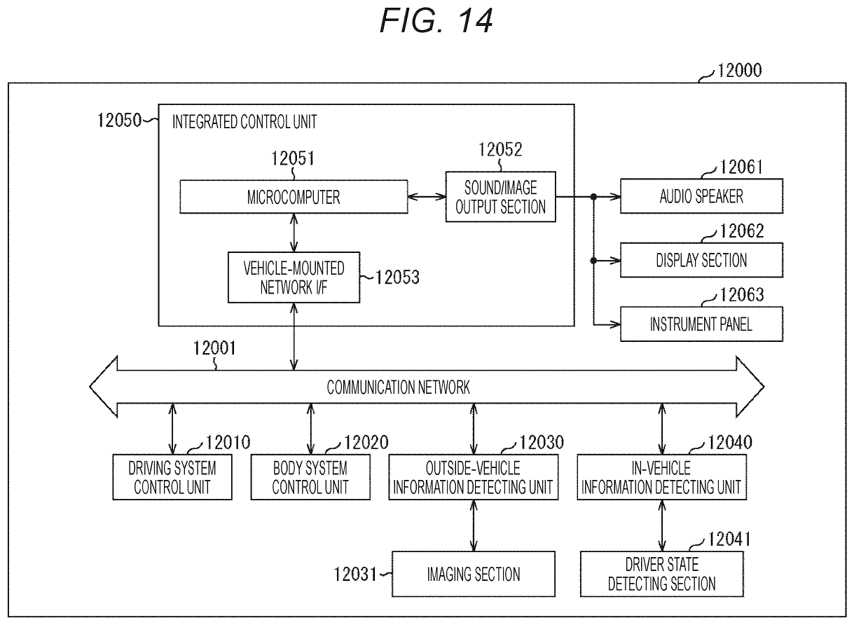

FIG. 14 is a block diagram showing a schematic configuration example of a vehicle control system that is an example of a mobile body control system to which the technology according to the present disclosure is applicable.

The vehicle control system 12000 includes a plurality of electronic control units connected to each other via a communication network 12001. In the example of FIG. 14, the vehicle control system 12000 includes a driving system control unit 12010, a body system control unit 12020, an outside-vehicle information detecting unit 12030, an in-vehicle information detecting unit 12040, and an integrated control unit 12050. Further, a microcomputer 12051, a sound/image output section 12052, and a vehicle-mounted network interface (I/F) 12053 are shown as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Further, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 14, an audio speaker 12061, a display section 12062, and an instrument panel 12063 are shown as the output device. The display section 12062 may, for example, include at least one of an on-board display and a head-up display.

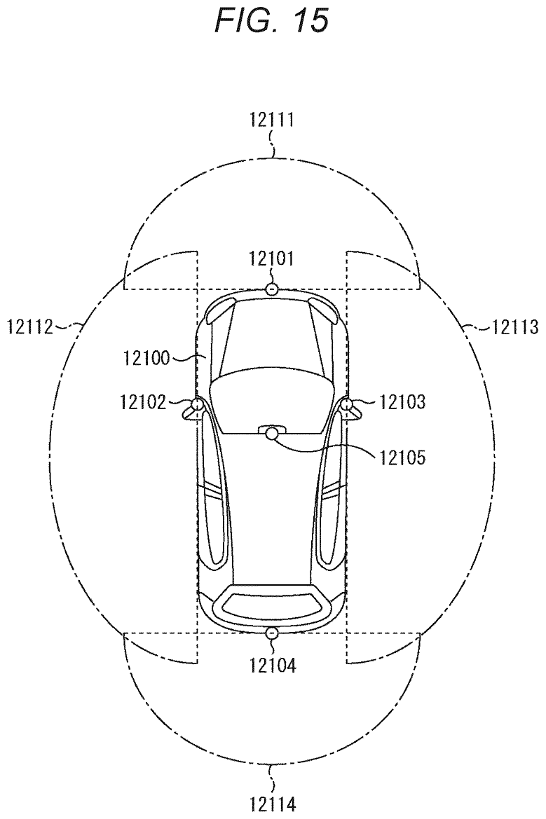

FIG. 15 shows an example of installation positions of the imaging sections 12031.

In FIG. 15, a vehicle 12100 includes imaging sections 12101, 12102, 12103, 12104, and 12105 as the imaging sections 12031.

The imaging sections 12101, 12102, 12103, 12104, and 12105 are provided, for example, at positions on a front nose, sideview mirrors, a rear bumper, and a back door of the vehicle 12100 as well as a position on an upper portion or the like of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors mainly obtain images of the sides of the vehicle 12100. The imaging section 12104 provided to the rear bumper or the back door obtains mainly an image of the rear of the vehicle 12100. The images of the front thereof obtained by the imaging sections 12101 and 12105 are mainly used to detect a preceding vehicle, a pedestrian, an obstacle, a traffic signal, a traffic sign, a lane, or the like.

Note that FIG. 15 shows an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure is applicable has been described above. The technology according to the present disclosure is applicable to the imaging section 12031, for example, among the configurations described above. Specifically, the solid-state imaging element described above can be mounted on the imaging section 12031. By applying the technology according to the present disclosure to the imaging section 12031, it is possible to obtain accurate distance information even if the size reduction is performed. As a result, it is possible to enhance functionality and safety of the vehicle 12100.

Note that the present technology can also employ the following configurations.

(1) A linear sensor including
a plurality of pixels each having a light receiving region that photoelectrically converts incident light and a non-light receiving region electrically connected to the light receiving region via a wire, in which
the light receiving regions in the respective plurality of pixels are collectively arranged while being separated from the non-light receiving regions.

(2) The linear sensor according to (1), in which the light receiving regions are arranged in a matrix.

(3) The linear sensor according to (1) or (2), in which the non-light receiving regions are arranged in a matrix.

(4) The linear sensor according to any one of (1) to (3), further including:
a first chip on which at least the light receiving regions are arranged;
a second chip laminated on the first chip; and
a frame memory that is arranged on the second chip and stores image data generated on the basis of photoelectric conversion of the light receiving regions.

(5) The linear sensor according to (4), in which the non-light receiving regions are arranged on the first chip.

(6) The linear sensor according to (5), in which the non-light receiving region has a larger area than the light receiving region.

(7) The linear sensor according to (4), in which
the non-light receiving regions are arranged on the second chip, and
the wire is a VLS wire extending in a lamination direction between the first chip and the second chip.

(8) The linear sensor according to (7), in which the light receiving region has a larger area than the non-light receiving region.

(9) The linear sensor according to (4), further including
a third chip laminated between the first chip and the second chip, in which
the non-light receiving regions are arranged on the third chip, and
the wire is a VLS wire extending in a lamination direction between the first chip and the third chip.

(10) The linear sensor according to (9), in which the light receiving region has an area equal to the non-light receiving region.

(11) The linear sensor according to any one of (1) to (10), further including:
a photoelectric conversion element that photoelectrically converts the incident light;
a floating diffusion layer that accumulates a charge generated by photoelectric conversion of the photoelectric conversion element;
a source follower transistor that amplifies a pixel signal generated on the basis of a charge amount accumulated in the floating diffusion layer; and
a pair of differential transistors that compares the pixel signal amplified by the source follower transistor with a reference signal.

(12) The linear sensor according to (11), in which
the photoelectric conversion element and the floating diffusion layer are arranged in the light receiving region, and
the source follower transistor and the pair of differential transistors are arranged in the non-light receiving region.

(13) The linear sensor according to (11), in which
the photoelectric conversion element, the floating diffusion layer, and the source follower transistor are arranged in the light receiving region, and
the pair of differential transistors is arranged in the non-light receiving region.

(14) The linear sensor according to (1), in which the one light receiving region is shared by the plurality of non-light receiving regions.

(15) The linear sensor according to (11), in which the photoelectric conversion element is a single photon avalanche diode (SPAD).

### REFERENCE SIGNS LIST

201 First chip
202 Second chip
203 Third chip
213 Wire
213c to 213f VLS wire
222 Photoelectric conversion element
224 Floating diffusion layer
231 Source follower transistor
257 Frame memory
220 Pixel
311 First differential transistor
312 Second differential transistor
2201 Light receiving region
2202 Non-light receiving region

1. A linear sensor comprising
a plurality of pixels each having a light receiving region that photoelectrically converts incident light and a non-light receiving region electrically connected to the light receiving region via a wire, wherein
the light receiving regions in the respective plurality of pixels are collectively arranged while being separated from the non-light receiving regions.

2. The linear sensor according to claim 1, wherein the light receiving regions are arranged in a matrix.

3. The linear sensor according to claim 2, wherein the non-light receiving regions are arranged in a matrix.

4. The linear sensor according to claim 1, further comprising:
a first chip on which at least the light receiving regions are arranged;
a second chip laminated on the first chip; and
a frame memory that is arranged on the second chip and stores image data generated on a basis of photoelectric conversion of the light receiving regions.

5. The linear sensor according to claim 4, wherein the non-light receiving regions are arranged on the first chip.

6. The linear sensor according to claim 5, wherein the non-light receiving region has a larger area than the light receiving region.

7. The linear sensor according to claim 4, wherein
the non-light receiving regions are arranged on the second chip, and
the wire is a VLS wire extending in a lamination direction between the first chip and the second chip.

8. The linear sensor according to claim 7, wherein the light receiving region has a larger area than the non-light receiving region.

9. The linear sensor according to claim 4, further comprising
a third chip laminated between the first chip and the second chip, wherein
the non-light receiving regions are arranged on the third chip, and
the wire is a VLS wire extending in a lamination direction between the first chip and the third chip.

10. The linear sensor according to claim 9, wherein the light receiving region has an area equal to the non-light receiving region.

11. The linear sensor according to claim 1, further comprising:
a photoelectric conversion element that photoelectrically converts the incident light;
a floating diffusion layer that accumulates a charge generated by photoelectric conversion of the photoelectric conversion element;
a source follower transistor that amplifies a pixel signal generated on a basis of a charge amount accumulated in the floating diffusion layer; and
a pair of differential transistors that compares the pixel signal amplified by the source follower transistor with a reference signal.

12. The linear sensor according to claim 11, wherein
the photoelectric conversion element and the floating diffusion layer are arranged in the light receiving region, and
the source follower transistor and the pair of differential transistors are arranged in the non-light receiving region.

13. The linear sensor according to claim 11, wherein
the photoelectric conversion element, the floating diffusion layer, and the source follower transistor are arranged in the light receiving region, and
the pair of differential transistors is arranged in the non-light receiving region.

14. The linear sensor according to claim 1, wherein the one light receiving region is shared by the plurality of non-light receiving regions.

15. The linear sensor according to claim 11, wherein the photoelectric conversion element is a single photon avalanche diode (SPAD).
